(19) United States
(12) Patent Application Publication
(10) Pub. No.: US 2014/0262463 A1
(43) Pub. Date: Sep. 18, 2014

(54) EMBEDDED MULTILAYER CERAMIC ELECTRONIC COMPONENT AND PRINTED CIRCUIT BOARD HAVING THE SAME

(71) Applicant: SAMSUNG ELECTRO-MECHANICS CO., LTD., Suwon (KR)

(72) Inventors: Byoung Hwa LEE, Suwon (KR); Doo Young KIM, Suwon (KR); Jin Woo LEE, Suwon (KR); Jin Man JUNG, Suwon (KR)

(73) Assignee: SAMSUNG ELECTRO-MECHANICS CO., LTD.

(21) Appl. No.: 13/941,172

(22) Filed: Jul. 12, 2013

(30) Foreign Application Priority Data
Mar. 14, 2013 (KR) 10-2013-0027534

(51) Int. Cl. H01G 4/01; H05K 1/18

(52) U.S. Cl. CPC H01G 4/01; H05K 1/183
USPC 174/260; 361/306.3

(57) ABSTRACT

There is provided an embedded multilayer ceramic electronic component including a ceramic body including dielectric layers, having first and second main surfaces, first and second side surfaces, and first and second end surfaces, and having a thickness of 250 μm or less, first and second internal electrodes alternately exposed to the first or second side surface, and first and second external electrodes formed on the first and second side surfaces, wherein the first external electrode includes a first electrode layer and a first metal layer, the second external electrode includes a second electrode layer and a second metal layer, the first and second external electrodes are extended onto the first and second main surfaces, and widths of the first and second external electrodes formed on the first and second main surfaces are different from each other.

### CROSS-REFERENCE TO RELATED APPLICATION

This application claims the priority of Korean Patent Application No. 10-2013-0027534 filed on Mar. 14, 2013, in the Korean Intellectual Property Office, the disclosure of which is incorporated herein by reference.

### BACKGROUND OF THE INVENTION

1. Field of the Invention

The present invention relates to an embedded multilayer ceramic electronic component and a printed circuit board having the same.

2. Description of the Related Art

In accordance with an increase in the density and integration of electronic circuits, the space in which passive elements are mounted on a printed circuit board has become insufficient. In order to solve this problem, efforts to implement a component embedded within a board, that is, an embedded device, have been undertaken. Particularly, various methods of embedding a multilayer ceramic electronic component used as a capacitive component in the board have been suggested.

As a method of embedding a multilayer ceramic electronic component in a board, there is provided a method of using a board material itself as a dielectric material for a multilayer ceramic electronic component and using a copper wiring, or the like, as an electrode for the multilayer ceramic electronic component. In addition, as further methods implementing an embedded multilayer ceramic electronic component, there are provided a method of forming an embedded multilayer ceramic electronic component by forming a high-k polymer sheet or thin-film dielectric in the board, a method of embedding a multilayer ceramic electronic component in a board, and the like.

Generally, the multilayer ceramic electronic component includes a plurality of dielectric layers formed of a ceramic material and internal electrodes interposed between the plurality of dielectric layers. The multilayer ceramic electronic component as described above is disposed within the board, whereby an embedded multilayer ceramic electronic component having a high degree of capacitance may be implemented.

In order to manufacture a printed circuit board having an embedded multilayer ceramic electronic component, after the multilayer ceramic electronic component is inserted into a core substrate, via holes are formed in upper and lower multilayer plates using laser in order to connect a substrate wiring and an external electrode of the multilayer ceramic electronic component to each other. This laser processing becomes a significant factor in increasing manufacturing costs.

In a process of embedding the embedded multilayer ceramic electronic component in the board, a heat treatment process for curing an epoxy resin and crystallizing a metal electrode is performed. In this case, a difference in coefficients of thermal expansion (CTE) among the epoxy resin, the metal electrode, a ceramic of the multilayer ceramic electronic component, and the like, or a defect on an adhesive surface between the board and the multilayer ceramic electronic component due to thermal expansion of the board may occur. This defect may cause delamination of the adhesive surface in a reliability test process.

Meanwhile, in the case in which a multilayer ceramic capacitor is used as a decoupling capacitor of a high performance integrated circuit (IC) power supply terminal such as an application processor of a smartphone or a central processing unit (CPU) of a personal computer (PC), when equivalent series inductance (hereinafter, referred to as “ESL”) increases, performance of an IC may be deteriorated. As performances of application processors provided in smartphones or in the CPUs of PCs have gradually improved, an influence of the increase in the ESL of the multilayer ceramic capacitor on the deterioration of the performance of the IC is also relatively increased.

A low inductance chip capacitor (LICC) is provided to decrease a distance between external terminals to allow for a decrease in a current flow path, thereby decreasing inductance of a capacitor.

Also in the case of the embedded multilayer ceramic electronic component, the LICC needs to be applied in order to decrease the inductance as described above.

However, in the case of the LICC, it may be difficult to implement a bandwidth of external electrodes at the same level as that of a general embedded multilayer ceramic electronic component.

Therefore, in the case of applying the LICC to the embedded multilayer ceramic electronic component, a processing area of a via for an electrical connection with a package substrate circuit is reduced, such that it may be difficult to embed the LICC in the board.

### RELATED ART DOCUMENT

Korean Patent Laid-Open Publication No. 2009-0083568

### SUMMARY OF THE INVENTION

An aspect of the present invention provides an embedded multilayer ceramic electronic component and a printed circuit board having the same.

According to an aspect of the present invention, there is provided an embedded multilayer ceramic electronic component including: a ceramic body including dielectric layers, having first and second main surfaces opposing each other, first and second side surfaces opposing each other, and first and second end surfaces opposing each other, and having a thickness of 250 μm or less; first and second internal electrodes disposed to face each other, having the dielectric layer interposed therebetween, and alternately exposed to the first side surface or the second side surface; and first and second external electrodes formed on the first and second side surfaces of the ceramic body, respectively, and electrically connected to the first and second internal electrodes, respectively, wherein the first external electrode includes a first electrode layer and a first metal layer formed on the first electrode layer, the second external electrode includes a second electrode layer and a second metal layer formed on the second electrode layer, the first and second external electrodes are extended onto the first and second main surfaces of the ceramic body, respectively, and widths of the first and second external electrodes formed on the first and second main surfaces are different from each other.

When the width of the first external electrode formed on the first and second main surfaces is BW1 and the width of the second external electrode formed on the first and second main surfaces is BW2, BW1>BW2 may be satisfied on the first main surface, and BW1<BW2 may be satisfied on the second main surface.

When a width of the ceramic body is W, the width BW1 of the first external electrode formed on the first main surface may satisfy 200 μm≦BW1≦W.

When a width of the ceramic body is W, the width BW2 of the second external electrode formed on the second main surface may satisfy 200 μm≦BW2≦W.

When the thickness of the ceramic body is a distance between the first and second main surfaces, a width of the ceramic body is a distance between the first side surface on which the first external electrode is formed and the second side surface on which the second external electrode is formed, and a length of the ceramic body is a distance between the first and second end surfaces, the width of the ceramic body may be less than or equal to the length of the ceramic body.

When the length of the ceramic body is L and the width of the ceramic body is W, 0.5 L≦W≦L may be satisfied.

When a thickness of each of the first and second metal layers is tp, tp≧5 μm may be satisfied.

When a surface roughness of each of the first and second metal layers is Ra2 and a thickness of each of the first and second metal layers is tp, 200 nm≦Ra2≦tp may be satisfied.

The first and second metal layers may include copper (Cu).

According to an aspect of the present invention, there is provided a printed circuit board having an embedded multilayer ceramic electronic component, including: an insulating substrate; and the embedded multilayer ceramic electronic component including a ceramic body including dielectric layers embedded in the insulating substrate, having first and second main surfaces opposing each other, first and second side surfaces opposing each other, and first and second end surfaces opposing each other, and having a thickness of 250 μm or less, first and second internal electrodes disposed to face each other, having the dielectric layer interposed therebetween, and alternately exposed to the first side surface or the second side surface, and first and second external electrodes formed on the first and second side surfaces of the ceramic body, respectively, and electrically connected to the first and second internal electrodes, respectively, wherein the first external electrode includes a first electrode layer and a first metal layer formed on the first electrode layer, the second external electrode includes a second electrode layer and a second metal layer formed on the second electrode layer, the first and second external electrodes are extended onto the first and second main surfaces of the ceramic body, respectively, and widths of the first and second external electrodes formed on the first and second main surfaces are different from each other.

When the width of the first external electrode formed on the first and second main surfaces is BW1 and the width of the second external electrode formed on the first and second main surfaces is BW2, BW1>BW2 may be satisfied on the first main surface, and BW1<BW2 may be satisfied on the second main surface.

When a width of the ceramic body is W, the width BW1 of the first external electrode formed on the first main surface may satisfy 200 μm≦BW1≦W.

When a width of the ceramic body is W, the width BW2 of the second external electrode formed on the second main surface may satisfy 200 μm≦BW2≦W.

When the thickness of the ceramic body is a distance between the first and second main surfaces, a width of the ceramic body is a distance between the first side surface on which the first external electrode is formed and the second side surface on which the second external electrode is formed, and a length of the ceramic body is a distance between the first and second end surfaces, the width of the ceramic body may be less than or equal to the length of the ceramic body.

When the length of the ceramic body is L and the width of the ceramic body is W, 0.5 L≦W≦L may be satisfied.

When a thickness of each of the first and second metal layers is tp, tp≧5 μm may be satisfied.

When a surface roughness of each of the first and second metal layers is Ra2 and a thickness of each of the first and second metal layers is tp, 200 nm≦Ra2≦tp may be satisfied.

The first and second metal layers may include copper (Cu).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing an embedded multilayer ceramic electronic component according to an embodiment of the present invention;

FIG. 2 is a view showing a ceramic body according to the embodiment of the present invention;

FIG. 3 is an exploded perspective view of FIG. 2;

FIG. 4 is a cross-sectional view taken along line X-X′ of FIG. 1;

FIG. 5 is an enlarged view of region A of FIG. 4; and

FIG. 6 is a cross-sectional view showing a printed circuit board having an embedded multilayer ceramic electronic component according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein.

Rather, these embodiments are provided so that this disclosure will be thorough and complete, and will fully convey the scope of the invention to those skilled in the art.

FIG. 1 is a perspective view showing an embedded multilayer ceramic electronic component according to an embodiment of the present invention.

FIG. 2 is a view showing a ceramic body according to the embodiment of the present invention.

FIG. 3 is an exploded perspective view of FIG. 2.

FIG. 4 is a cross-sectional view taken along line X-X′ of FIG. 1.

FIG. 5 is an enlarged view of region A of FIG. 4.

Referring to FIGS. 1 through 5, the embedded multilayer ceramic electronic component according to the embodiment of the present invention may include a ceramic body 10 including dielectric layers 11, having first and second main surfaces S1 and S2 opposing each other, first and second side surfaces S5 and S6 opposing each other, and first and second end surfaces 3 and S4 opposing each other, and having a thickness of 250 μm or less; first and second internal electrodes 21 and 22 disposed to face each other, having the dielectric layer 11 interposed therebetween, and alternately exposed to the first side surface S5 or the second side surface S6; and first and second external electrodes 31 and 32 formed on the first and second side surfaces S5 and S6 of the ceramic body 10, respectively, and electrically connected to the first and second internal electrodes 21 and 22, respectively, wherein the first external electrode 31 includes a first electrode layer 31a and a first metal layer 32a formed on the first electrode layer 31a, the second external electrode 32 includes a second electrode layer 32a and a second metal layer 32b formed on the second electrode layer 32a, the first and second external electrodes 31 and 32 are extended onto the first and second main surfaces S1 and S2 of the ceramic body 10, respectively, and widths of the first and second external electrodes 31 and 32 formed on the first and second main surfaces S1 and S2 are different from each other.

Hereinafter, the multilayer ceramic electronic component according to the embodiment of the present invention will be described. Particularly, a multilayer ceramic capacitor will be described. However, the present invention is not limited thereto.

In the multilayer ceramic capacitor according to the embodiment of the present invention, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1. Here, the ‘thickness direction’ is the same as a direction in which dielectric layers are stacked, that is, a ‘stacking direction’.

According to the embodiment of the present invention, the ceramic body 10 may have the first and second main surfaces S1 and S2 opposing each other and the first and second side surfaces S5 and S6 and the first and second end surfaces S3 and S4 that connect the first and second main surfaces to each other. A shape of the ceramic body 10 is not particularly limited, but may be a hexahedral shape as shown in the drawing.

According to the embodiment of the present invention, a raw material forming the dielectric layer 11 is not particularly limited as long as sufficient capacitance may be obtained therewith, and may be, for example, a barium titanate (BaTiO₃) powder.

In a material forming the dielectric layer 11, various ceramic additives, organic solvents, plasticizers, binders, dispersing agents, and the like, may be applied to a powder such as a barium titanate (BaTiO₃) powder, or the like, according to a purpose of the present invention.

An average particle size of a ceramic powder used to form the dielectric layer 11 is not particularly limited, but may be adjusted in order to accomplish the purpose of the present invention. For example, the average particle size may be adjusted to be 400 nm or less.

A material forming the first and second internal electrodes 21 and 22 is not particularly limited, but may be a conductive paste formed of at least one selected from a group consisting of, for example, a noble metal material such as palladium (Pd), a palladium-silver (Pd—Ag) alloy, or the like, nickel (Ni), and copper (Cu).

The first and second internal electrodes 21 and 22 may be disposed to face each other, having the dielectric layer 11 interposed therebetween, and may be alternately exposed to the first side surface S5 or the second side surface S6.

The first and second internal electrodes 21 and 22 are alternately exposed to the first side surface S5 or the second side surface S6, whereby a reverse geometry capacitor (RGC) or a low inductance chip capacitor (LICC) may be implemented as described below.

The ceramic body 10 may have of a thickness ts of 250 μm or less.

As described above, the ceramic body 10 is manufactured to have the thickness ts of 250 μm or less, such that it may be appropriate for an embedded multilayer ceramic capacitor.

In addition, the thickness ts of the ceramic body 10 may be a distance between the first and second main surfaces S1 and S2.

According to the embodiment of the present invention, the ceramic body 10 may have the first and second external electrodes 31 and 32 formed on an outer side thereof, wherein the first and second external electrodes 31 and 32 include the first and second electrode layers 31a and 32a and the first and second metal layers 31b and 32b formed on the first and second electrode layers, respectively.

In order to form capacitance, the first and second electrode layers 31a and 32a may be formed on the outer side of the ceramic body 10 and may be electrically connected to the first and second internal electrodes 21 and 22, respectively.

The first and second electrode layers 31a and 32a may be formed of the same conductive material as that of the first and second internal electrodes 21 and 22, but are not limited thereto. For example, the first and second electrode layers 31a and 32a may be formed of copper (Cu), silver (Ag), nickel (Ni), or the like.

The first and second electrode layers 31a and 32a may be formed by applying and then sintering conductive pastes prepared by adding glass frit to the metal powder.

A general multilayer ceramic capacitor may have a length longer than a width thereof and include external electrodes disposed on end surfaces opposing each other in a length direction of a ceramic body.

In this case, since a current path may be elongated at the time of applying alternating current (AC) electricity to the external electrode, a larger current loop may be formed, and a magnitude of an induced magnetic field may be increased, such that inductance may be increased.

In the multilayer ceramic capacitor according to the embodiment of the present invention, the first and second external electrodes 31 and 32 may be formed on the first and second side surfaces S5 and S6 of the ceramic body 10 in order to decrease the current path.

A width W of the ceramic body 10 may be a distance between the first side surface S5 on which the first external electrode 31 is formed and the second side surface S6 on which the second external electrode 32 is formed, and a length L of the ceramic body 10 may be a distance between the first and second end surfaces S3 and S4.

According to the embodiment of the present invention, the width W between the first and second side surfaces S5 and S6 on which the first and second external electrodes 31 and 32 are formed, respectively, may be less than or equal to the length L between the first and second end surfaces S3 and S4.

Therefore, since a distance between the first and second external electrodes 31 and 32 is decreased, a current path may be decreased. As a result, a current loop may be decreased to decrease inductance.

The multilayer ceramic electrode component as described above, in which the first and second external electrodes 31 and 32 are formed on the first and second side surfaces S5 and S6 of the ceramic body 10, respectively, such that the width W of the ceramic body 10 (that is, the distance between the first and second external electrodes 31 and 32) is less than or equal to the length L of the ceramic body 10, may be called a reverse geometry capacitor (RGC) or a low inductance chip capacitor (LICC).

In addition, when the length of the ceramic body 10 is L and the width thereof is W, 0.5 L≦W≦L may be satisfied. However, the present invention is not limited thereto.

The length and the width of the ceramic body are adjusted so as to satisfy 0.5 L≦W≦L, whereby the inductance of the multilayer ceramic capacitor may be decreased.

Therefore, the multilayer ceramic electronic component according to the embodiment of the present invention may implement relatively low inductance, such that electrical performance thereof may be improved.

According to the embodiment of the present invention, the first and second metal layers 31b and 32b including copper (Cu) may be formed on the first and second electrode layers 31a and 32a, respectively.

Generally, since the multilayer ceramic capacitor is mounted on the printed circuit board, a nickel/tin plated layer may commonly be formed on the external electrode.

However, the multilayer ceramic capacitor according to the embodiment of the present invention, to be embedded in the printed circuit board, is not mounted on the board, but a circuit of the board may be electrically connected to the first and second external electrodes 31 and 32 of the multilayer ceramic capacitor by a via formed of a copper (Cu) material.

Therefore, according to the embodiment of the present invention, the first and second metal layers 31b and 32b may include copper (Cu) for good electrical connectivity with the copper (Cu), a material of the via formed in the board.

A method of forming the first and second metal layers 31b and 32b including the copper (Cu) is not particularly limited. For example, the first and second metal layers 31b and 32b may be formed by plating. In this case, the first and second metal layers 31b and 32b may be formed of a plated layer including the copper (Cu).

Referring to FIGS. 4 and 5, the first and second external electrodes 31 and 32 may be extended onto the first and second main surfaces S1 and S2 of the ceramic body 10, respectively, and the widths of the first and second external electrodes 31 and 32 formed on the first and second main surfaces S1 and S2 may be different from each other.

In the case in which a general multilayer ceramic capacitor is used as a decoupling capacitor of a high performance integrated circuit (IC) power supply terminal such as an application processor of a smartphone or a central processing unit (CPU) of a personal computer (PC), equivalent series inductance (hereinafter, referred to as “ESL”) increases, such that performance of an IC may be deteriorated.

Particularly, as performance of the application processor of the smartphone or the CPU of the PC has gradually improved, an influence of the increase in the ESL of the multilayer ceramic capacitor on the deterioration of the performance of the IC is relatively increased.

In order to solve the above-mentioned problem, also in the case of the embedded multilayer ceramic electronic component, the low inductance chip capacitor (LICC) needs to be applied in order to decrease the inductance as described above.

However, in the low inductance chip capacitor (LICC), it may be difficult to implement a bandwidth of external electrodes at the same level as that of a general embedded multilayer ceramic electronic component.

Therefore, in the case of applying the low inductance chip capacitor (LICC) to the embedded multilayer ceramic electronic component, a processing area of a via for an electrical connection with a package substrate circuit is reduced, such that it is difficult to embed the LICC in the board.

According to the embodiment of the present invention, the first and second external electrodes 31 and 32 are extended onto the first and second main surfaces S1 and S2 of the ceramic body 10, respectively, and the widths of the first and second external electrodes 31 and 32 formed on the first and second main surfaces S1 and S2 are different from each other, such that the above-mentioned problem may be solved.

Particularly, the width of the first external electrode 31 or the second external electrode 32 formed on the first and second main surfaces S1 and S2 is significantly increased, whereby even in the case that the LICC is applied to the embedded multilayer ceramic electronic component, a bandwidth of the external electrode may be implemented at the same level as that of the general embedded multilayer ceramic electronic component.

Therefore, even in the case that the embedded multilayer ceramic electronic component according to the embodiment of the present invention is applied, a defect may be prevented at the time of processing the via for electrical connection with the package substrate circuit.

According to the embodiment of the present invention, when the width of the first external electrode 31 formed on the first and second main surfaces S1 and S2 is BW1 and the width of the second external electrode 32 formed on the first and second main surfaces S1 and S2 is BW2, BW1>BW2 may be satisfied on the first main surface S1, and BW1<BW2 may be satisfied on the second main surface S2.

That is, the widths of the first and second external electrodes are adjusted so as to satisfy BW1>BW2 on the first main surface S1 and satisfy BW1<BW2 on the second main surface S2, whereby the bandwidth of the external electrode may be implemented at the same level as that of the general embedded multilayer ceramic electronic component.

Although the case in which BW1>BW2 is satisfied on the first main surface S1 and BW1<BW2 is satisfied on the second main surface S2 has been described in the embodiment of the present invention, the present invention is not limited thereto. That is, BW1<BW2 may be satisfied on the first main surface S1 and BW1>BW2 may be satisfied on the second main surface S2.

Particularly, when the width of the ceramic body 10 is W, the width BW1 of the first external electrode 31 formed on the first main surface S1 may satisfy 200 μm≦BW1≦W, but is not necessarily limited thereto.

In addition, when the width of the ceramic body 10 is W, the width BW2 of the second external electrode 32 formed on the second main surface S2 may satisfy 200 μm≦BW2≦W, but is not necessarily limited thereto.

The width BW1 of the first external electrode 31 is adjusted so as to satisfy 200 μm≦BW1≦W and the width BW2 of the second external electrode 32 is adjusted so as to satisfy 200 μm≦BW2≦W as described above, whereby the bandwidth of the external electrode at the same level as that of the general embedded multilayer ceramic electronic component as well as the low inductance may be implemented.

Therefore, a defect may be prevented at the time of processing the via for electrical connectivity between the embedded multilayer ceramic electronic component and the package substrate circuit.

In the case in which each of the widths BW1 and BW2 of the first and second external electrodes 31 and 32 is less than 200 μm, a contact defect problem with the circuit and the via may occur at the time of embedding the multilayer ceramic capacitor in the board.

Meanwhile, according to the embodiment of the present invention, the width BW1 of the first external electrode 31 formed on the first main surface S1 may coincide with the width W of the ceramic body 10, and the width BW2 of the second external electrode 32 formed on the second main surface S2 may coincide with the width W of the ceramic body 10.

In this case, the first and second external electrodes 31 and 32 may be formed on only any one of the first and second main surfaces S1 and S2, a processing defect may be prevented in the via at the time of embedding the multilayer ceramic capacitor in the board, and a contact detect with the package substrate circuit may be more certainly prevented.

Meanwhile, according to the embodiment of the present invention, the ceramic body 10 may include an active layer including the first and second internal electrodes 21 and 22 and a cover layer formed on an upper surface or a lower surface of the active layer.

The ceramic body 10 may include the active layer including the first and second internal electrodes 21 and 22, wherein the active layer refers to a layer contributing to forming capacitance.

In addition, the ceramic body 10 may include the cover layer formed on the upper surface or the lower surface of the active layer.

In addition, when a thickness of each of the first and second metal layers 31b and 32b is tp, tp≧5 μm may be satisfied.

The thickness tp of each of the first and second metal layers 31b and 32b may satisfy tp≧5 μm, but is not limited thereto. That is, the thickness tp of each of the first and second metal layers 31b and 32b may be 15 μm or less.

The thickness tp of each of the first and second metal layers 31b and 32b is adjusted so as to satisfy tp≧5 μm and become 15 μm or less, whereby the multilayer ceramic capacitor capable of excellently processing the via in the board and having excellent reliability may be implemented.

In the case in which the thickness tp of each of the first and second metal layers 31b and 32b is less than 5 μm, when the multilayer ceramic electronic component is embedded in the printed circuit board 100, a defect that a conductive via hole 140 is connected up to the ceramic body 10 may occur at the time of processing the conductive via hole 140.

In the case in which the thickness tp of each of the first and second metal layers 31b and 32b exceeds 15 μm, a crack may occur in the ceramic body 10 due to stress of the metal layers 31b and 32b.

Meanwhile, when a surface roughness of each of the first and second metal layer 31b and 32b is Ra2 and the thickness of each of the first and second metal layers 31b and 32b is tp, 200 nm≦Ra2≦tp may be satisfied.

The surface roughness of each of the first and second metal layer 31b and 32b is adjusted so as to satisfy 200 nm≦Ra2≦tp, whereby a delamination phenomenon between the multilayer ceramic electronic component and the board may be improved and a crack may be prevented.

The surface roughness indicates a degree of fine concave and convex portions generated on a metal surface when the metal surface is processed.

The surface roughness may be created by a tool used for processing the metal surface, depending on whether or not such a processing method is appropriate, scratches generated in the surface, oxidation, and the like. In representing a degree of roughness, a cross section of a surface taken by cutting the surface on a plane perpendicular to the surface may be formed in a shape of a curved line, and a height from the lowest portion of this curved line to the highest portion thereof may be called a center line average roughness and be represented by Ra.

In the embodiment of the present invention, a center line average roughness of each of the first and second metal layers 31b and 32b will be defined as Ra2.

FIG. 5 is an enlarged view of region A representing the center line average roughness Ra2 of each of the first and second metal layers 31b and 32b in FIG. 4.

Referring to FIG. 5, in the multilayer ceramic electronic component according to the embodiment of the present invention, when the surface roughness of each of the first and second metal layer 31b and 32b is Ra2 and the thickness of each of the first and second metal layers 31b and 32b is tp, 200 nm≦Ra2≦tp may be satisfied.

In detail, a method of calculating the center line average roughness Ra2 of each of the first and second metal layers 31b and 32b will be described. First, a virtual center line may be drawn with respect to roughness portions formed on one surface of the first and second metal layers 31b and 32b.

Next, the respective distances (for example, r₁, r₂, r₃ . . . r₁₃) may be measured based on the virtual center line of the roughness, an average value of the respective distances may be calculated by the following Equation, and the center line average roughness Ra2 of each of the first and second metal layers 31b and 32b may be calculated using the calculated value.

$${R}_{a} = \frac{\vert {r}_{1} \vert + \vert {r}_{2} \vert + \vert {r}_{3} \vert + … \vert {r}_{n} \vert}{n}$$

The center line average roughness Ra2 of each of the first and second metal layers 31b and 32b is adjusted in a range of 200 nm≦Ra2≦tp, whereby the multilayer ceramic electronic component having excellent withstand voltage characteristics, improved adhesion with the board, and excellent reliability may be implemented.

In the case in which the surface roughness of each of the first and second metal layers 31a and 32b is less than 200 nm, a delamination phenomenon between the multilayer ceramic electronic component and the board may occur.

Meanwhile, in the case in which the surface roughness of each of the first and second metal layer 31b and 32b exceeds the thickness tp of each of the first and second metal layers 31b and 32b, cracks may occur.

In addition, a thickness tc of the cover layer may be 1 μm or more to 30 μm or less, but is not limited thereto.

In the case in which the thickness tc of the cover layer is less than 1 μm, the thickness of the cover layer may be very thin, such that external impacts may be transferred to the active layer, an internal capacitance forming part, whereby a defect may occur, and in the case in which the thickness tc of the cover layer exceeds 30 μm, the thickness of the cover layer may be very thick, such that the capacitance forming part is relatively small, whereby it may be difficult to implement capacitance.

The thicknesses of the first and second metal layers 31b and 32b and the cover layer may be average thicknesses.

The average thicknesses of the first and second metal layers 31b and 32b and the cover layer may be measured in an image obtained by scanning a cross section of the ceramic body 10 in the length direction thereof using a scanning electronic microscope (SEM), as shown in FIG. 4.

For example, as shown in FIG. 4, the thicknesses of the first and second metal layers 31b and 32b and the cover layer may be measured in an image obtained by scanning a cross section in length and thickness (L-T) directions taken at a central portion of the ceramic body 10 in the width (W) direction thereof using the scanning electronic microscope (SEM).

Hereinafter, a method of manufacturing an embedded multilayer ceramic electronic component according to the embodiment of the present invention will be described. However, the present invention is not limited thereto.

The method of manufacturing an embedded multilayer ceramic electronic component according to the embodiment of the present invention may include preparing ceramic green sheets including dielectric layers; forming internal electrode patterns on the ceramic greens sheet using conductive pastes for an internal electrode including conductive metal powders and ceramic powders; multi-layering the ceramic green sheets having the internal electrode patterns formed thereon to form an active layer including first and second internal electrodes disposed to face each other and multi-layering the ceramic green sheet on an upper surface or a lower surface of the active layer to form a cover layer, thereby preparing a ceramic body having first and second main surfaces opposing each other, first and second side surfaces opposing each other, and first and second end surfaces opposing each other; forming first and second electrode layers on the first and second side surfaces of the ceramic body and forming first and second metal layers including copper (Cu) on the first and second electrode layers, respectively, to prepare first and second external electrodes; and applying a sand blasting process to the first and second metal layers to adjust a surface roughness, wherein the first and second external electrodes are extended onto the first and second main surfaces of the ceramic body, respectively, and widths of the first and second external electrodes formed on the first and second main surfaces are different from each other.

In the method of manufacturing an embedded multilayer ceramic electronic component according to the embodiment of the present invention, first, a slurry including powder such as barium titanate (BaTiO₃) powder, or the like, may be applied to and dried on a carrier film to prepare a plurality of ceramic green sheets, thereby forming a dielectric layer.

The ceramic green sheet may be prepared by manufacturing slurry by mixing ceramic powder, a binder, and a solvent with each other and forming the slurry as a sheet having a thickness of several μm by a doctor blade method.

Next, the conductive paste for an internal electrode including nickel powder in an amount of 40 to 50 parts by weight of nickel particles having an average particle size of 0.1 to 0.2 μm are prepared.

After the conductive paste for an internal electrode is applied to the ceramic green sheet by a screen printing method to form the internal electrode, 400 to 500 ceramic green sheets are multi-layered to form the active layer, and the ceramic green sheet is multi-layered on the upper surface or the lower surface of the active layer to form the cover layer, thereby manufacturing the ceramic body 10 having the first and second main surfaces opposing each other, the first and second side surfaces opposing each other, and the first and second end surfaces opposing each other.

Then, the first and second electrode layers may be formed on the first and second side surfaces of the ceramic body, respectively. Next, the first and second metal layers including the copper (Cu) may be formed on the first and second external electrodes, respectively.

The forming of the first and second metal layers including the copper (Cu) is not particularly limited, but may be performed by, for example, plating.

In the forming of the first and second metal layers 31b and 32b including the copper (Cu) on the first and second electrode layers 31a and 32a, respectively, a sand blasting process may be applied in order to artificially form and adjust a surface roughness of each of the first and second metal layers 31b and 32b including the copper (Cu) after sintering of the ceramic body 10 is completed.

Since the sand blasting process may increase only the surface roughness of each of the first and second metal layers 31b and 32b including the copper (Cu), it does not have an effect on reliability of the multilayer ceramic electronic component.

A description of portions having the same feature as that of the embedded multilayer ceramic electronic component according to the embodiment of the present invention will be omitted.

FIG. 6 is a cross-sectional view showing a printed circuit board 200 having an embedded multilayer ceramic electronic component according to another embodiment of the present invention.

Since the embedded multilayer ceramic electronic component shown in FIG. 6 is substantially the same as the embedded multilayer ceramic electronic component 100 described above with reference to FIGS. 1 through 5, components that are the same as or similar to those of the embedded multilayer ceramic electronic component 100 described above with reference to FIGS. 1 through 5 are denoted by the same reference numerals, and an overlapped description will be omitted.

Referring to FIG. 6, the printed circuit board 200 having an embedded multilayer ceramic electronic component according to another embodiment of the present invention may include an insulating substrate 110; and the embedded multilayer ceramic electronic component 100 including a ceramic body 10 including dielectric layers 11, having first and second main surfaces S1 and S2 opposing each other, first and second side surfaces S5 and S6 opposing each other, and first and second end surfaces S3 and S4 opposing each other, and having a thickness of 250 μm or less, first and second internal electrodes 21 and 22 disposed to face each other, having the dielectric layer 11 interposed therebetween, and alternately exposed to the first side surface S5 or the second side surface S6, and first and second external electrodes 31 and 32 formed on the first and second side surfaces S5 and S6 of the ceramic body 10, respectively, and electrically connected to the first and second internal electrodes 21 and 22, respectively, wherein the first external electrode 31 includes a first electrode layer 31a and a first metal layer 32a formed on the first electrode layer 31a, the second external electrode 32 includes a second electrode layer 32a and a second metal layer 32b formed on the second electrode layer 32a, the first and second external electrodes 31 and 32 are extended onto the first and second main surfaces S1 and S2 of the ceramic body 10, respectively, and widths of the first and second external electrodes 31 and 32 formed on the first and second main surfaces S1 and S2 are different from each other.

A thickness is of the ceramic body 10 may be a distance between the first and second main surfaces S1 and S2.

In the multilayer ceramic capacitor 100 included in the printed circuit board 200 having an embedded multilayer ceramic electronic component according to the embodiment of the present invention, the first and second external electrodes 31 and 32 may be formed on the first and second side surfaces S5 and S6 of the ceramic body 10 in order to decrease the current path.

A width W of the ceramic body 10 may be a distance between the first side surface S5 on which the first external electrode 31 is formed and the second side surface S6 on which the second external electrode 32 is formed, and a length L of the ceramic body 10 may be a distance between the first and second end surfaces S3 and S4.

According to the embodiment of the present invention, the width W between the first and second side surfaces S5 and S6 on which the first and second external electrodes 31 and 32 are formed, respectively, may be less than or equal to the length L between the first and second end surfaces S3 and S4.

Therefore, since a distance between the first and second external electrodes 31 and 32 is decreased, a current path may be decreased. As a result, a current loop may be decreased to decrease inductance.

The multilayer ceramic electrode component as described above in which the first and second external electrodes 31 and 32 are formed on the first and second side surfaces S5 and S6 of the ceramic body 10, respectively, such that the width W of the ceramic body 10 (that is, the distance between the first and second external electrodes 31 and 32) is less than or equal to the length L of the ceramic body 10 may be called a reverse geometry capacitor (RGC) or a low inductance chip capacitor (LICC).

The insulating substrate 110 may have a structure in which it includes insulating layers 110a, 110b, and 110c, and may include conductive patterns 120 and conductive via holes 140 that configure inter-circuits in various forms as shown in FIG. 6 if necessary. The insulating substrate 110 may be the printed circuit board 200 including the multilayer ceramic electronic component 110 therein.

After the multilayer ceramic electronic component 100 is inserted into the printed circuit board 200, it may be subjected to several severe environments, such as that of a heat treatment and the like, during post-processing of the printed circuit board 200.

Particularly, in the heat treatment process, contraction and expansion of the printed circuit board 200 may be directly transferred to the multilayer ceramic electronic component inserted into the printed circuit board 200 to apply stress to an adhesive surface between the multilayer ceramic electronic component and the printed circuit board 200.

In the case in which the stress applied to the adhesive surface between the multilayer ceramic electronic component and the printed circuit board 200 is higher than adhesion strength therebetween, a delamination phenomenon that the adhesive surface is delaminated may occur.

The adhesion strength between the multilayer ceramic electronic component and the printed circuit board 200 is in proportion to electrochemical coupling force between the multilayer ceramic electronic component and the printed circuit board 200 and an effective surface area of the adhesive surface between the multilayer ceramic electronic component and the printed circuit board 200. Therefore, the surface roughness of the multilayer ceramic electronic component is controlled in order to improve the effective surface area of the adhesive surface between the multilayer ceramic electronic component and the printed circuit board 200, whereby the delamination phenomenon between the multilayer ceramic electronic component 100 and the printed circuit board 200 may be improved. In addition, an occurrence frequency of delamination on the adhesive surface between the multilayer ceramic electronic component 100 and the printed circuit board 200 according to the surface roughness of the multilayer ceramic electronic component 100 embedded in the printed circuit board 200 may be confirmed.

Hereafter, although the present invention will be described in detail with reference to Inventive Example, it is not limited thereto.

### Inventive Example 1

In order to confirm whether or not a contact defect between a multilayer ceramic capacitor and a via formed in a board has occurred according to a width of each of the first and second external electrodes formed on first and second main surfaces of an embedded multilayer ceramic electronic component according to Inventive Example, whether or not a defect has occurred at the time of processing a via according to a thickness of each of the first and second metal layers 31b and 32b, and an occurrence frequency of delamination on an adhesive surface according to a surface roughness of each of the first and second metal layers 31b and 32b, after a board having a multilayer ceramic electronic component embedded therein is left at a temperature of 85° C. and a relative humidity of 85%, general conditions of a chip component for a mobile phone mother board, for thirty minutes, the respective experiments were performed while changing the width of each of the first and second external electrodes and the thickness and the surface roughness of each of the first and second metal layers 31b and 32b.

The following Table 1 illustrates whether or not the contact defect between the multilayer ceramic capacitor and the via formed in the board occurred, according to the width of each of the first and second external electrodes formed on first and second main surfaces.

TABLE 1

| Width of external electrode (μm) | Judgment |
|---|---|
| Less130 | x |
| 130 to140 | x |
| 140 to150 | x |
| 150 to160 | x |
| 160 to170 | x |
| 170 to180 | Δ |
| 180 to 190 | ∘ |
| 190 to 200 | ∘ |
| 200 to 210 | ⊚ |
| 210 or more | ⊚ |

x: Defect rate of 20% or more
Δ: Defect rate of 5% to 20%
∘: Defect rate of 0.01% to 5%
⊚: Defect rate less than 0.01%

Referring to the above Table 1, it can be appreciated that in the case in which the width of each of the first and second external electrodes is 200 μm or more, there is no contact defect between the multilayer ceramic capacitor and the via formed in the board.

On the other hand, it can be appreciated that in the case in which the width of each of the first and second external electrodes is less than 200 μm, there is a contact defect between the multilayer ceramic capacitor and the via formed in the board.

The following Table 2 illustrates whether or not defects occurred at the time of processing the via according to the thickness of each of the first and second metal layers 31b and 32b.

TABLE 2

| Thickness of metal layer (μm) | Judgment |
|---|---|
| Less 1 | x |
| 1 to 2 | x |
| 2 to 3 | x |
| 3 to 4 | Δ |
| 4 to 5 | ∘ |
| 5 to 6 | ⊚ |
| 6 or more | ⊚ |

x: Defect rate of 10% or more
Δ: Defect rate of 1% to 10%
∘: Defect rate of 0.01% to 1%
⊚: Defect rate less than 0.01%

Referring to the above Table 2, it can be appreciated that in the case in which the thickness of each of the metal layers 31b and 32b is 5 μm or more, the multilayer ceramic capacitor capable of excellently processing the via in the board and having excellent reliability may be implemented.

On the other hand, it can be appreciated that in the case in which the thickness of each of the metal layers 31b and 32b is less than 5 μm, defects may occur at the time of processing the via in the board.

The following Table 3 illustrates the occurrence frequency of delamination on the adhesive surface according to the surface roughness of each of the first and second metal layers 31b and 32b.

TABLE 3

| Surface roughness of metal layer (nm) | Judgment |
|---|---|
| Less than 50 | x |
| 50 to 100 | x |
| 100 to 150 | Δ |
| 150 to 200 | ∘ |
| 200 to 250 | ⊚ |
| 250 or more | ⊚ |

x: Defect rate of 5% or more
Δ: Defect rate of 1% to 5%
∘: Defect rate of 0.01% to 1%
⊚: Defect rate less than 0.01%

Referring to the above Table 3, it can be appreciated that in the case in which the surface roughness of each of the first and second metal layers 31b and 32b is 200 nm or more, the occurrence frequency of delamination on the adhesive surface is relatively low, such that the multilayer ceramic capacitor having excellent reliability may be implemented.

On the other hand, it can be appreciated that in the case in which the surface roughness of each of the first and second metal layers 31b and 32b is less than 200 nm, the occurrence frequency of delamination on the adhesive surface is increased, such that reliability is decreased.

As set forth above, the multilayer ceramic electronic component according to the embodiment of the present invention may implement relatively low inductance, such that electrical performance thereof may be improved.

In addition, according to the embodiment of the present invention, the bandwidth of the external electrode at the same level as that of the general multilayer ceramic capacitor as well as the low inductance may be implemented, such that a defect may be prevented at the time of processing the via for electrical connection with a package substrate circuit.

Further, according to the embodiment of the present invention, the surface roughness of the metal layer is adjusted, whereby a delamination phenomenon between the multilayer ceramic electronic component and the board may be decreased to improve adhesion characteristics.

While the present invention has been shown and described in connection with the embodiments, it will be apparent to those skilled in the art that modifications and variations can be made without departing from the spirit and scope of the invention as defined by the appended claims.

What is claimed is:

1. An embedded multilayer ceramic electronic component comprising:
a ceramic body including dielectric layers, having first and second main surfaces opposing each other, first and second side surfaces opposing each other, and first and second end surfaces opposing each other, and having a thickness of 250 μm or less;
first and second internal electrodes disposed to face each other, having the dielectric layer interposed therebetween, and alternately exposed to the first side surface or the second side surface; and
first and second external electrodes formed on the first and second side surfaces of the ceramic body, respectively, and electrically connected to the first and second internal electrodes, respectively,
wherein the first external electrode includes a first electrode layer and a first metal layer formed on the first electrode layer, the second external electrode includes a second electrode layer and a second metal layer formed on the second electrode layer, the first and second external electrodes are extended onto the first and second main surfaces of the ceramic body, respectively, and widths of the first and second external electrodes formed on the first and second main surfaces are different from each other.

2. The embedded multilayer ceramic electronic component of claim 1, wherein when the width of the first external electrode formed on the first and second main surfaces is BW1 and the width of the second external electrode formed on the first and second main surfaces is BW2, BW1>BW2 is satisfied on the first main surface, and BW1<BW2 is satisfied on the second main surface.

3. The embedded multilayer ceramic electronic component of claim 2, wherein when a width of the ceramic body is W, the width BW1 of the first external electrode formed on the first main surface satisfies 200 μm≦BW1≦W.

4. The embedded multilayer ceramic electronic component of claim 2, wherein when a width of the ceramic body is W, the width BW2 of the second external electrode formed on the second main surface satisfies 200 μm≦BW2≦W.

5. The embedded multilayer ceramic electronic component of claim 1, wherein when the thickness of the ceramic body is a distance between the first and second main surfaces, a width of the ceramic body is a distance between the first side surface on which the first external electrode is formed and the second side surface on which the second external electrode is formed, and a length of the ceramic body is a distance between the first and second end surfaces, the width of the ceramic body is less than or equal to the length of the ceramic body.

6. The embedded multilayer ceramic electronic component of claim 5, wherein when the length of the ceramic body is L and the width of the ceramic body is W, 0.5 L≦W≦L is satisfied.

7. The embedded multilayer ceramic electronic component of claim 1, wherein when a thickness of each of the first and second metal layers is tp, tp≧5 μm is satisfied.

8. The embedded multilayer ceramic electronic component of claim 1, wherein when a surface roughness of each of the first and second metal layers is Ra2 and a thickness of each of the first and second metal layers is tp, 200 nm≦Ra2≦tp is satisfied.

9. The embedded multilayer ceramic electronic component of claim 1, wherein the first and second metal layers include copper (Cu).

10. A printed circuit board having an embedded multilayer ceramic electronic component, comprising:
an insulating substrate; and
the embedded multilayer ceramic electronic component including a ceramic body including dielectric layers embedded in the insulating substrate, having first and second main surfaces opposing each other, first and second side surfaces opposing each other, and first and second end surfaces opposing each other, and having a thickness of 250 μm or less, first and second internal electrodes disposed to face each other, having the dielectric layer interposed therebetween, and alternately exposed to the first side surface or the second side surface, and first and second external electrodes formed on the first and second side surfaces of the ceramic body, respectively, and electrically connected to the first and second internal electrodes, respectively, wherein the first external electrode includes a first electrode layer and a first metal layer formed on the first electrode layer, the second external electrode includes a second electrode layer and a second metal layer formed on the second electrode layer, the first and second external electrodes are extended onto the first and second main surfaces of the ceramic body, respectively, and widths of the first and second external electrodes formed on the first and second main surfaces are different from each other.

11. The printed circuit board having an embedded multilayer ceramic electronic component of claim 10, wherein when the width of the first external electrode formed on the first and second main surfaces is BW1 and the width of the second external electrode formed on the first and second main surfaces is BW2, BW1>BW2 is satisfied on the first main surface, and BW1<BW2 is satisfied on the second main surface.

12. The printed circuit board having an embedded multilayer ceramic electronic component of claim 11, wherein when a width of the ceramic body is W, the width BW1 of the first external electrode formed on the first main surface satisfies 200 μm≦BW1≦W.

13. The printed circuit board having an embedded multilayer ceramic electronic component of claim 11, wherein when a width of the ceramic body is W, the width BW2 of the second external electrode formed on the second main surface satisfies 200 μm≦BW2≦W.

14. The printed circuit board having an embedded multilayer ceramic electronic component of claim 10, wherein when the thickness of the ceramic body is a distance between the first and second main surfaces, a width of the ceramic body is a distance between the first side surface on which the first external electrode is formed and the second side surface on which the second external electrode is formed, and a length of the ceramic body is a distance between the first and second end surfaces, the width of the ceramic body is less than or equal to the length of the ceramic body.

15. The printed circuit board having an embedded multilayer ceramic electronic component of claim 14, wherein when the length of the ceramic body is L and the width of the ceramic body is W, 0.5 L≦W≦L is satisfied.

16. The printed circuit board having an embedded multilayer ceramic electronic component of claim 10, wherein when a thickness of each of the first and second metal layers is tp, tp≧5 μm is satisfied.

17. The printed circuit board having an embedded multilayer ceramic electronic component of claim 10, wherein when a surface roughness of each of the first and second metal layers is Ra2 and a thickness of each of the first and second metal layers is tp, 200 nm≦Ra2≦tp is satisfied.

18. The printed circuit board having an embedded multilayer ceramic electronic component of claim 10, wherein the first and second metal layers include copper (Cu).
